(19) United States
(12) Patent Application Publication
(10) Pub. No.: US 2017/0176496 A1
(43) Pub. Date: Jun. 22, 2017

(54) SPACE TRANSFORMER INCLUDING A PERFORATED MOLD PREFORM FOR ELECTRICAL DIE TEST

(71) Applicants: Akshay Mathkar, Tempe, AZ (US); Nachiket R. Raravikar, Gilbert, AZ (US); James C. Matayabas, Jr., Gilbert, AZ (US); Jin Yang, Hillsboro, OR (US)

(72) Inventors: Akshay Mathkar, Tempe, AZ (US); Nachiket R. Raravikar, Gilbert, AZ (US); James C. Matayabas, Jr., Gilbert, AZ (US); Jin Yang, Hillsboro, OR (US)

(21) Appl. No.: 14/975,386

(22) Filed: Dec. 18, 2015

(51) Int. Cl. G01R 1/073; G01R 31/28; H01F 38/20; H01F 41/02; H01F 27/28; H01F 27/29

(52) U.S. Cl. CPC G01R 1/07314; H01F 27/2804; H01F 27/29; H01F 38/20; H01F 41/02; G01R 31/2884

(57) ABSTRACT

Prober space transformer to interface an E-testing apparatus to an unpackaged die. The space transformer may include a substrate and a perforated cover plate disposed on the substrate. The substrate may include conductive traces and an array of conductive probe pins extend outwardly from anchor points on the substrate. The pins are electrically coupled to at least one of the conductive traces on the substrate as a prober interface between an E-testing apparatus and a DUT. The cover plate may be affixed to a surface of the substrate and includes an array of perforations through which the array of conductive pins may pass. The cover plate may be synthetic polymer resin or a polymer-based composite, fabricated, for example by perforating a mold preform.

### BACKGROUND

In the integrated circuit (IC) industry, devices fabricated in parallel on a large substrate, such as a 300 mm or 450 mm wafer, are typically sorted based on an electrical test (E-test) at the back end of line (BEOL). The devices are singulated into chips following a backside wafer grind. Singulated die identified good at the BEOL E-test are then assembled into a package. A final functional test of the packaged die is then performed. As post-singulation die processing and package assembly practices become more complex, it becomes more important to perform one or more E-test on unpackaged die, for example to filter out die that passed BEOL E-test but have since become unsuitable for packaging.

E-testing of unpackaged die is a significant challenge because of the small dimensions, and vast number of testable points (e.g. top-level metallization) on modern ICs. For example, a microprocessor die may have thousands of testable points. E-testing of a packaged die is comparatively easy as the package assembly breaks out the top-level die metallization (e.g., having a pitch of 100 μm, or less) to packaged electrical connections of much larger dimensions. To perform a comprehensive E-test on an unpackaged die, a prober of an electrical testing apparatus (E-tester) may be coupled to a die through a space transforming prober interface.

During testing, the space transformer must withstand repetitive interfacing with consecutive unpackaged die under test (DUT). Top-level interconnect geometries (e.g., having a pitch of 100 μm, or less) must be accommodated as they are scaled, so electrical probe pin dimensions and alignment are critical to ensure accurate testing without damage to the DUT. Furthermore, many testing algorithms place the DUT under thermal stress, for example testing at temperatures of 200° C., or more. Therefore the space transformer must also be robust to such thermal cycling.

Space transformer architecture is therefore important for high E-tester up-time.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an isometric view of an electrical testing apparatus for unpackaged die, in accordance with some embodiments;

FIG. 2A, 2B, and 2C are isometric views of a space transformer assembly for electrical die test, in accordance with some embodiments;

FIG. 3A and 3B are cross-sectional views illustrating an effect of CTE mismatch between components of a space transformer compared to well-matched components, in accordance with some embodiments;

FIG. 4 is a flow diagram illustrating a method of fabricating a space transformer cover plate, in accordance with some embodiments; and

FIG. 5A, 5B, and 5C illustrate cross-sectional views of a through hole in a space transformer cover plate as selected operations of the method in FIG. 4 are performed, in accordance with some embodiments; and

FIG. 5D illustrates a cross-sectional view of through holes in a space transformer cover plate, in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present embodiments may be practiced without these specific details. In some instances, well-known methods and devices are shown in block diagram form, rather than in detail, to avoid obscuring features of the exemplary embodiments. Reference throughout this specification to “an embodiment” or “one embodiment” means that a particular feature, structure, function, or characteristic described in connection with the embodiment is included in at least one embodiment. Thus, the appearances of the phrase “in an embodiment” or “in one embodiment” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the exemplary embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Described herein are exemplary embodiments of a prober space transformer to interface an E-testing apparatus to an unpackaged die under test. In some embodiments, the space transformer includes a substrate and a perforated cover plate disposed on the substrate.

The substrate includes conductive traces and an array of conductive probe pins extend outwardly from anchor points on the substrate. The pins are electrically coupled to at least one of the conductive traces on the substrate as a prober interface between an E-testing apparatus and a DUT. The cover plate may be affixed to a surface of the substrate and includes an array of perforations through which the array of conductive pins may pass. The cover plate may provide one or more of lateral pin support and support and/or protection to the underlying substrate and conductive traces. The cover plate may be synthetic polymer resin or polymer-based composite, fabricated, for example by perforating a mold preform.

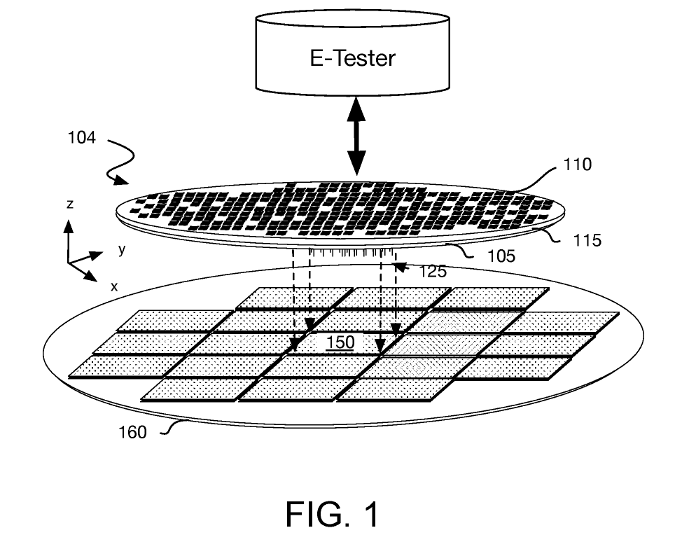

FIG. 1 is an isometric view of an electrical testing apparatus 101 for an unpackaged DUT 150, in accordance with some embodiments. Apparatus 101 includes an electrical tester (E-tester) 102 electrically coupled to a space transformer 104. In some embodiments, E-tester 102 is commercially available automated test equipment (ATE) configured for functionality, performance, and/or stress testing of an IC. Electrical coupling 103 between E-tester 102 and space transformer 104 may be any known prober Interface Test Adapter (ITA). Space transformer 104 further provides electronic connections between electrical coupling 103 and unpackaged DUT 150. In the illustrated embodiment, space transformer 104 includes a substrate 115 and electrical coupling 103 makes electrical connections to metallization 110 disposed on a fist side of substrate 115. Substrate 115 further includes conductive trace routing electrically coupling metallization 110 to a probe pin array 125 extending from a second side of substrate 115. Substrate 115 may further include additional circuitry to adapt signals between the E-tester 102 and unpackaged DUT 150. In some exemplary embodiments, substrate 115 is an organic polymer, which may advantageously facilitate fabrication of probe pin array 125. Substrate 115 may therefore have a relatively low Young's modulus, rendering it susceptible to wear during testing operations.

Unpackaged DUT 150 is disposed on a carrier 160. In some embodiments, DUT 150 is a thinned die that has been singulated, for example by a laser scribing operation. Carrier 160 may be a membrane, such as a backside tape applied after a backside grind operation. During an electrical die testing operation, test points on DUT 150 are to be aligned with probe pin array 125 and brought into electrical contact with probe pin array 125, for example by an ATE handler. In some embodiments, conductive features in a top-level of metallization on DUT 150 (e.g., a bump or an under bump metallization) are brought into contact with probe pin array 125 and an electrical test algorithm is executed on the DUT through the array of conductive pins. As such, space transformer 104 may supplant the role of a DUT socket typically employed to bridge the connection between a prober ITA and a packaged DUT. Similar to a socket, space transformer 104 is to be robust enough to withstand the rigors of high volume testing and/or comprise an assembly. In exemplary embodiments where substrate 115 is an organic polymer, space transformer 104 is an assembly including a perforated cover plate or sheet 105 affixed to substrate 115 so as to be disposed between unpackaged DUT 150 and substrate 115. Advantageously, perforated cover plate 105 has a higher modulus than that of substrate 115, improving the wear characteristics of space transformer 104. As described further below, cover plate 105 is advantageously a dielectric material and includes no circuitry and/or metallization traces.

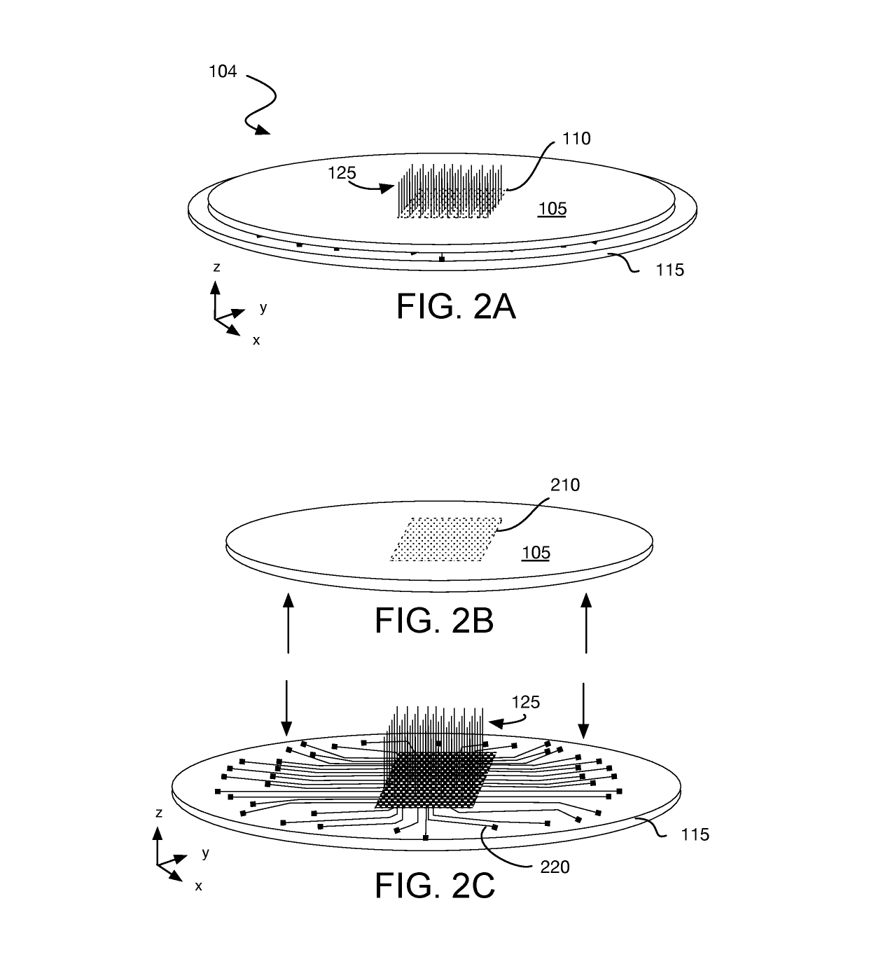

FIG. 2A, 2B, and 2C are isometric views of space transformer 104 for electrical die test, in accordance with some embodiments. In FIG. 2A, space transformer 104 is inverted from the configuration illustrated in FIG. 1. Perforated plate 105 is affixed as a cover over substrate 115, for example protecting a surface where probe pin array 125 is anchored to substrate 115. As further illustrated in FIG. 2B and FIG. 2C, cover plate 105 is affixed to substrate 115, for example with an adhesive. Cover plate 105 includes a two-dimensional array of perforations 210 centrally located on the plate to accommodate passage of probe pin array 125. The perforation array 210 is dimensioned to accommodate any number of probe pins as a function of test points available on the DUT. In some microprocessor embodiments, for example, perforation array 210 extends over an area of 1 cm², or more. In some further embodiments, perforation array 210 extends at least 1 cm in at least one dimension of the array (e.g., x-dimension). Probe pin dimensions may vary, but in some exemplary embodiments a single probe pin has a diameter below 50 μm, and advantageously below 40 μm. Probe pins of such diameter may extend outwardly from substrate 115 by about 300 μm, or more. As further illustrated in FIG. 2C, substrate 115 includes a plurality of conductive traces 220 that break out from the dense probe pin array 125, for example with a single trace electrically coupled to an anchored end of one pin of probe pin array 125. After breakout, traces 220 may pass vertically through substrate 115 to metallization 110 (FIG. 1).

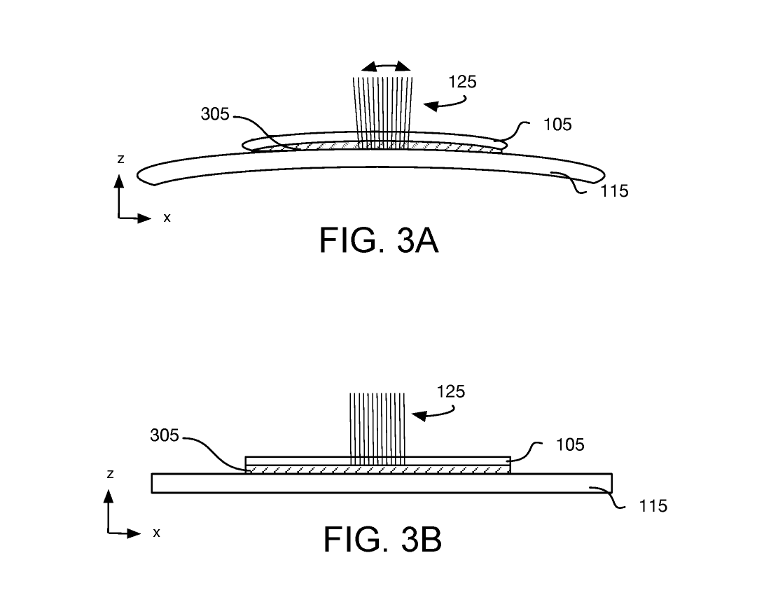

In some advantageous embodiments, cover plate 105 is a synthetic polymer resin or polymer composite material having a significantly higher storage modulus than that of substrate 115. The polymeric material advantageously has a modulus that is at least twice that of substrate 115, and more advantageously three times that of substrate 115, or more. In some exemplary embodiments, the polymeric material has a modulus of at least 15 GPa, and ideally 20 GPa, or more, at 23° C. The polymeric material advantageously also has a CTE (e.g., at least in the x or y dimension) well-matched to that of substrate 115. A better CTE match between substrate 115 and perforated cover plate 105 reduces thermo-mechanical stresses experienced by space transformer 104. In some embodiments where a DUT is thermally stressed during a testing operation, space transformer 104 may also experience thermal cycles between room temperature (e.g., 23° C.) and an elevated testing temperature, which is typically limited only by the DUT metallization reflow temperature (e.g., 250° C., or more). FIG. 3A and 3B are cross-sectional views of cover plate 105 affixed to substrate 115 with an adhesive layer 305. FIG. 3A illustrates space transformer warpage at an elevated testing temperature resulting from CTE mismatch between an organic polymer space transformer substrate (e.g., having a CTE of about 20 ppm/° C.) and a ceramic perforated cover plate (CTE of about 3 ppm/° C.). As shown in FIG. 3A, warpage in space transformer 104 may further induce misalignment in probe pines 123 that hinder contact with a DUT. In the illustrated example where thermal expansion experienced by substrate 115 exceeds that of perforated cover plate 105, the effective pitch of probe pin array 125 is reduced by curvature in space transformer 104. A short between probe pins may occur if the CTE mismatch is severe and mis-probing can occur with less extreme warpage. Components of the space transformer assembly illustrated in FIG. 3B have a matched CTE. While the ideal CTE of the perforated plate depends on the composition of substrate 115, in some advantageous embodiments where substrate 115 comprises an organic polymeric material, the CTE of perforated plate 105 is at least 15 ppm/° C., and advantageously 20 ppm/° C., or more. A number of commercially available polymer resin systems have in-plane CTE values within this range.

Some synthetic polymer resins are known to possess both a relatively high CTE and modulus. A polymer resin may also be advantageously compatible with laser ablation. Exemplary polymeric resins include one or more of epoxy acrylate, epoxy novalac acrylate, methacrylate, polyimide, bismaleimide, polyurethane, polycarbonate, polyester, phenol, and benzocyclobutene. Formulations including one more of these may have a CTE in the range of 9-20 ppm/° C., or higher. Polymer resins may experience a dramatic increase in CTE upon reaching the glass transition temperature (T_{g}). CTE_{α,1} is typically much less than CTE_{α,2}. Polymer resins having a T_{g} that exceeds the maximum e-testing temperature are advantageous so that CTE_{α,1} is not exceeded. In some embodiments, the polymer resin T_{g} is at least 225° C., and advantageously of 250° C., or more.

Filler may be added to form a polymeric composite having a greater modulus than a pure resin. Exemplary fillers include one or more of silica particles, ceramic particles, glass fibers, or aramid fibers. Although fibers may be woven, non-woven embodiments may advantageously ablate more uniformly. The addition of fillers also may reduce the CTE of the composite from that of the pure resin, so while the amount of filler may vary, filler below 40 wt% may be advantageous for matching the CTE of an organic substrate and ablating uniformly. In some advantageous embodiments, the resin composite is a prepreg sheet. Various polymer resins systems listed above may be acquired in the prepreg format. For example, a polyimide resin coated aramid fiber prepreg with a reasonably high modulus values and in-plane CTE is commercially available from DuPont Co. under the trade name Thermount®.

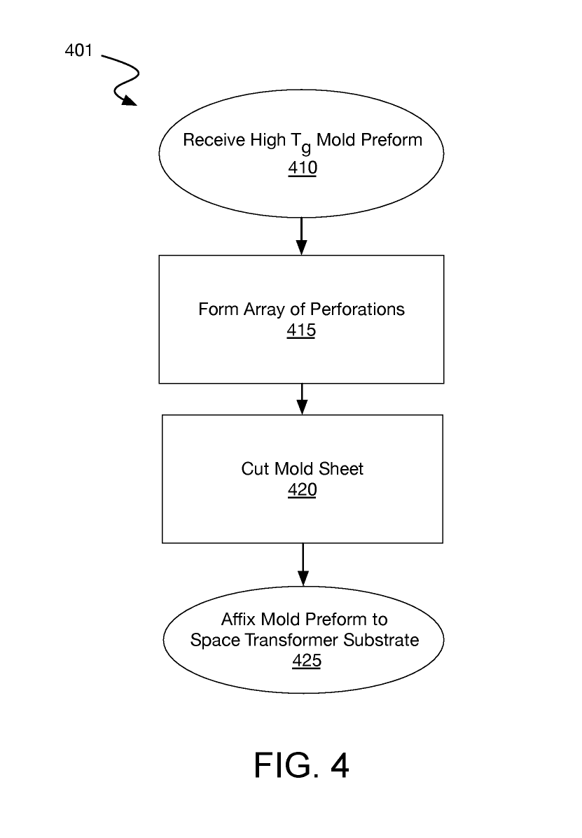

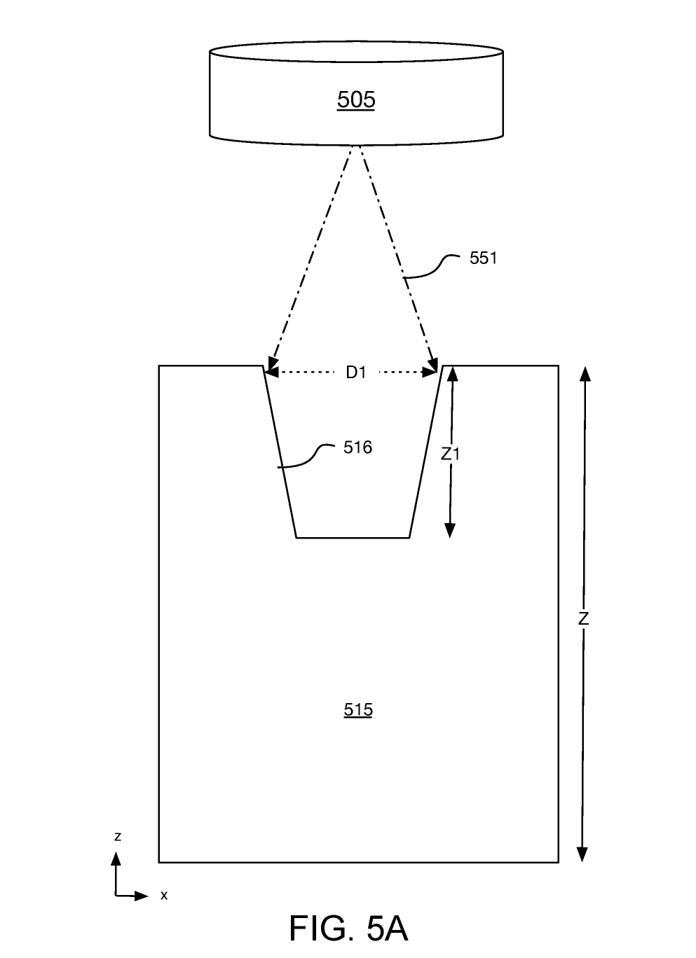

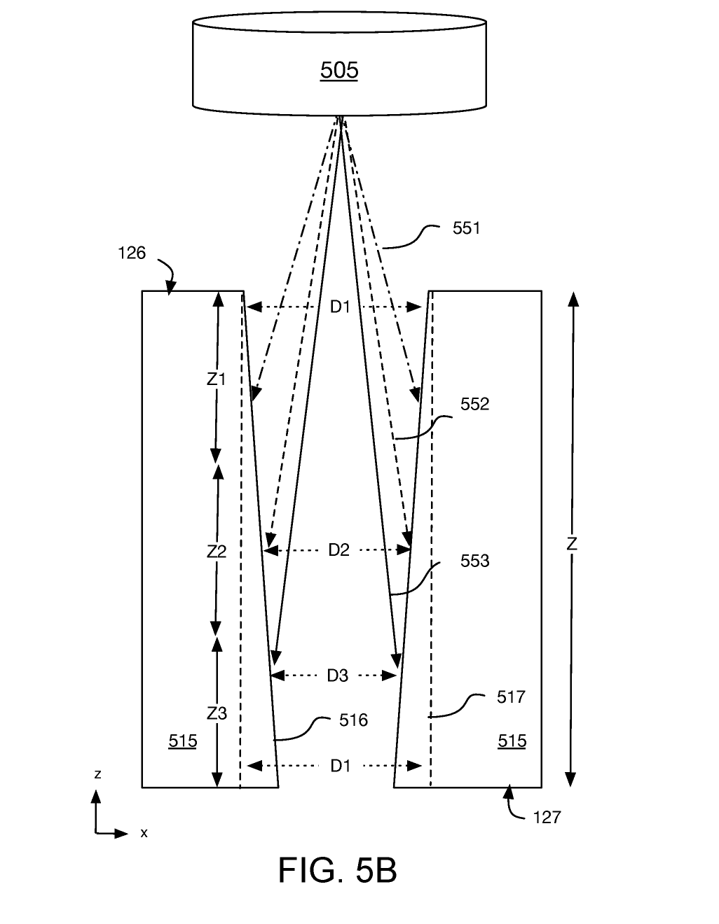

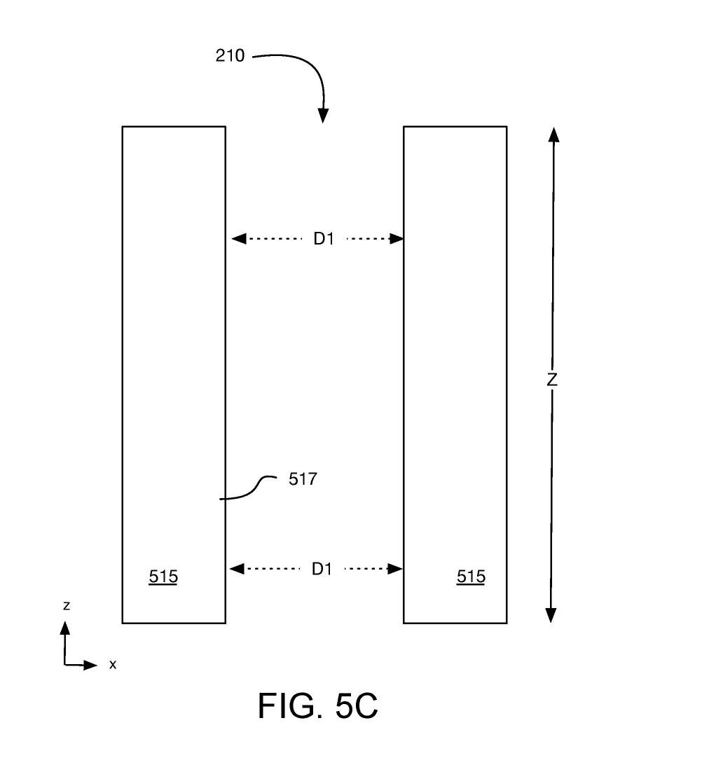

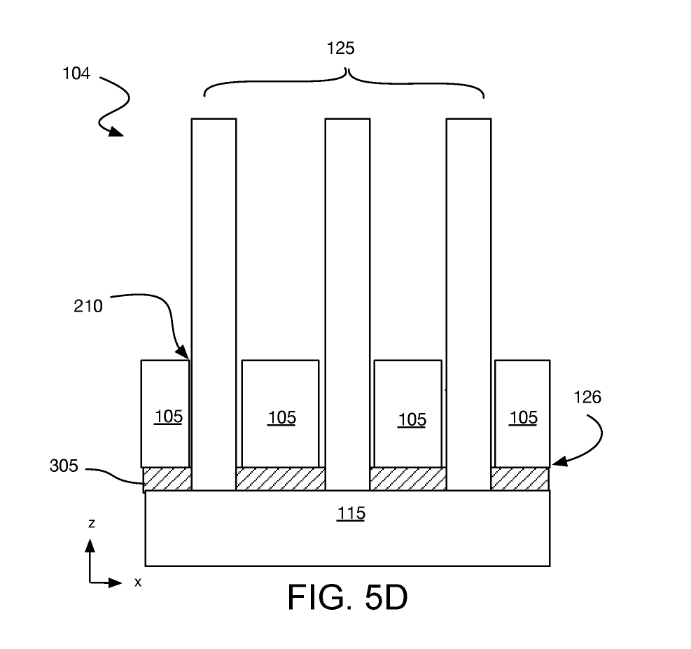

FIG. 4 is a flow diagram illustrating a method 401 for fabricating a space transformer cover plate, in accordance with some embodiments. FIG. 5A-5C illustrate cross-sectional views of a through hole in a space transformer cover plate as selected operations of the method in FIG. 4 are performed, in accordance with some embodiments.

Referring first to FIG. 4, at operation 410 a high T_{g} mold preform is received. The mold preform may be a polymer resin or resin composite, such as any of those described above. As received, the preform may be partially cured (i.e., not fully hardened) or fully cured. In some embodiments, operation 410 further entails polishing one or more surfaces of the mold preform to achieve a uniform thickness advantageously 300 μm, or less (e.g., 200-300 μm).

At operation 415 through hole perforations are drilled into the mold preform at the desired pitch to form a 2D perforation array (e.g., 50 μm, or less, at a pitch of 90-110 μm, or less) matching the probe pin array. Any known laser drilling (ablation) process may be employed at operation 415. FIG. 5A, 5B illustrates some exemplary embodiments where the mold preform is laser ablated. Laser ablation rates may be advantageously increased for polymer resin systems with a higher crosslink density (e.g., generated from a precursor with a greater amount of curing agents). The addition of filler may also impact the via depth profiles due to dissimilar ablation rates, so the composition of the polymer composite may be dependent on the techniques employed to drill the perforations. Polymer resins and composites are susceptible to developing significant sidewall taper/slope during laser ablation as a function of limited heat dissipation. In some embodiments, angle of incidence of a beam spot having a significantly smaller spot diameter than that of the through hole is dynamically adjusted during ablation to direct beam energy toward the sidewall as ablation progresses. As shown in FIG. 5A for example, output from laser 550 is controlled to emit a beam spot along a first beam path 510 associated with a fist angle of incidence to a top surface of polymer resin preform 515. A beam spot of 5 μm, for example, may follow a first beam path 551 with a minimum diameter D₁ (e.g., less than 60 m). The first beam path 551 may result in ablation of polymer 515 to a first depth Z₁. Angle of sidewall 516 may be less than normal to the polished preform surface (e.g., 70-80°.

As shown in FIG. 5B, output from laser 550 is subsequently controlled to emit a beam spot along a second beam path 552 associated with a second (e.g., steeper) angle of incidence that intersects a bottom portion of sloped sidewall 516 formed with the first beam path. The angle of sidewall 516 may then be increased toward that of sidewall 517 (e.g., 80-90°) while ablating a to a second depth Z₂. This process may be iterated (e.g., with additional beam paths 553) as needed to clear a through hole in polymer resin preform 515 of minimum diameter D₁. Upon completion of operation 425, through holes may have minimal taper, for example as illustrated in FIG. 5C. Alternatively, the through hole sidewall may be permitted to have significant taper (e.g., sidewall slope<80°, rendering the polymer resin preform 515 “sided” with one surface (e.g., 126 in FIG. 5B) having a larger through hole diameter D₁ and the opposite surface (e.g., 127 in FIG. 5B) having a smaller through hole diameter D₃. For such embodiments, the minimum hole diameter D₃ is to be larger than the probe pin diameter (e.g., ˜50 μm).

Returning to FIG. 4, at operation 425 the mold preform may be cut and/or shaped as needed to form a cover plate that accommodates the shape of the space transformer substrate (e.g., round with a predetermined diameter). The polymer resin-based cover plate including a plurality of perforations is then affixed to the space transformer substrate at operation 425 to complete method 401. Operation 425 may entail gluing the perforated composite cover plate to the space transformer substrate with any adhesive material known to be suitable for the expected maximum e-test temperature (e.g., 250° C.).

FIG. 5D illustrates a sectional view of space transformer 104 including a polymer resin/composite cover plate 105 having a plurality of perforations 210. Space transformer 104 may be an output of method 401, for example. In some embodiments where perforations have significant sidewall taper (e.g., 80°, or less), the cover plate surface at an end of the through hole having a larger diameter is affixed to the substrate. For example, embodiments with sloped sidewalls 516 (FIG. 5B), cover plate surface 126 is glued to substrate 115 to ensure cover plate surface 127 interfaces with the DUT and provides a bushing of minimum diameter about the circumference of probe pins 125 at a distance from substrate 115 equal to approximately the thickness of cover plate 105 (e.g., 300 μm).

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

In one or more first embodiments, an electrical-test (E-test) prober space transformer comprises a substrate including a plurality of conductive traces, each of the traces to electrically couple with an electrical testing apparatus. The space transformer further comprises an array of conductive pins, each of the pins extending outwardly from a first pin end anchored to the substrate and electrically coupled to at least one of the conductive traces. The spacer transformer further comprises a perforated sheet of polymer resin, or a composite thereof, affixed to a surface of the substrate, and including an array of perforations through which the conductive pins pass.

In furtherance of the first embodiments, the perforated sheet has a lateral coefficient of thermal expansion (CTE) of at least 9 ppm/° C. and a storage modulus of at least 15 GPa at 23° C.

In furtherance of the first embodiments, the perforated sheet has a glass transition temperature of at least 225° C.

In furtherance of the first embodiments, the perforated sheet comprises a polymeric resin impregnated with filler.

In furtherance of the first embodiments immediately above, the polymeric resin is selected from the group consisting of: epoxy acrylate; epoxy novalac acrylate; methacrylate; polyimide; bismaleimide; polyurethane; polycarbonate; polyester; phenol; and benzocyclobutene.

In furtherance of the first embodiments immediately above, the filler is selected from the group consisting of: silica particles, ceramic particles, glass, and aramid fibers.

In furtherance of the first embodiments, the perforated sheet comprises a polyimide resin and a non-woven aramid filler.

In furtherance of the first embodiments, the perforated sheet comprises a polymeric resin impregnated with at least 80 wt % filler.

In furtherance of the first embodiments, the array of perforations is least 1 cm long in at least one dimension, the perforated sheet has a thickness of at least 200 μm, and the array of perforations comprises a plurality of perforations, each of the plurality having a minimum diameter less than 60 μm and a pitch less than 150 μm.

In furtherance of the first embodiments, the space transformer further comprising an adhesive layer disposed between the perforated sheet and the substrate.

In one or more second embodiment, a method for fabricating an electrical-test prober space transformer comprises receiving a substrate including a plurality of conductive traces and an array of conductive pins, each of the pins extending outwardly from a first pin end anchored to the substrate and electrically coupled to at least one of the conductive traces. The method comprises receiving a mold preform sheet comprising a polymer resin. The method comprises forming an array of perforations through the mold preform sheet. The method comprises affixing the mold preform sheet to a surface of the substrate with the array of conductive pins passing through the array of perforations.

In furtherance of the second embodiments, forming the array of perforations further comprises selectively laser ablating the mold preform sheet.

In furtherance of the second embodiments immediately above, the laser ablating comprises forming a through hole having a minimum diameter less than 60 μm, and a sidewall angle no less than 70°.

In furtherance of the second embodiments, forming the array of perforations further comprises selectively laser ablating the mold preform sheet, and selectively laser ablating the mold preform sheet further comprises ablating a first thickness of the mold preform sheet by directing a laser light beam at a first angle of incidence along a first circular path defining the perforation perimeter, and ablating a second thickness of the mold preform sheet by directing a laser light beam at a second angle of incidence along a second circular path intersecting a sidewall of the first thickness.

In furtherance of the second embodiments, the mold preform sheet comprises a resin composite material with a lateral coefficient of thermal expansion (CTE) of at least 9 ppm/° C. and a storage modulus of at least 15 GPa at 23° C.

In furtherance of the second embodiments immediately above, the resin composite has a glass transition temperature of at least 220° C.

In furtherance of the second embodiments immediately above, the resin composite comprises a polymeric matrix resin impregnated with filler.

In furtherance of the second embodiments, affixing the mold preform sheet to a surface of the substrate further comprises applying an adhesive to a surface of at least one of the mold preform sheet and substrate.

In one or more third embodiments, a method of testing a singulated unpackaged die comprises aligning the die to an array of conductive pins disposed on a space transformer, the pins extending outwardly from first pin ends electrically coupled to conductive traces disposed on a space transformer substrate, and the pins passing through a perforated mold preform sheet affixed to a surface of the substrate by an adhesive, the mold preform sheet comprising a polymer resin. The method further comprising contacting a top metallization level of the die with second pin ends of the conductive pin array, and the method comprising executing an electrical test algorithm on the die through the array of conductive pins.

In furtherance of the third embodiments, the mold preform sheet comprises a resin composite with a lateral coefficient of thermal expansion (CTE) of at least 9 ppm/° C. and a storage modulus of at least 15 GPa at 23° C., and has a glass transition temperature of at least 225° C.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An electrical-test (E-test) prober space transformer, comprising:
a substrate including a plurality of conductive traces, each of the traces to electrically couple with an electrical testing apparatus;
an array of conductive pins, each of the pins extending outwardly from a first pin end anchored to the substrate and electrically coupled to at least one of the conductive traces; and
a perforated sheet of polymer resin, or a composite thereof, affixed to a surface of the substrate, and including an array of perforations through which the array of conductive pins pass.

2. The prober space transformer of claim 1, wherein the perforated sheet has a lateral coefficient of thermal expansion (CTE) of at least 9 ppm/° C. and a storage modulus of at least 15 GPa at 23° C.

3. The prober space transformer of claim 1, wherein the perforated sheet has a glass transition temperature of at least 225° C.

4. The prober space transformer of claim 1, wherein the perforated sheet comprises a polymeric resin impregnated with filler.

5. The prober space transformer of claim 4, wherein the polymeric resin is selected from the group consisting of: epoxy acrylate; epoxy novalac acrylate; methacrylate; polyimide; bismaleimide; polyurethane; polycarbonate; polyester; phenol; and benzocyclobutene.

6. The prober space transformer of claim 5, wherein the filler is selected from the group consisting of: silica particles, ceramic particles, glass, and aramid fibers.

7. The prober space transformer of claim 4, wherein the perforated sheet comprises a polyimide resin and a non-woven aramid filler.

8. The prober space transformer of claim 4, wherein the perforated sheet comprises no more than 40 wt % filler.

9. The prober space transformer of claim 4, wherein:
the array of perforations is least 1 cm long in at least one dimension;
the perforated sheet has a thickness of at least 200 μm; and
the array of perforations comprises a plurality of perforations, each of the plurality having a minimum diameter less than 60 μm and a pitch less than 150 μm.

10. The prober space transformer of claim 1, further comprising an adhesive layer disposed between the perforated sheet and the substrate.

11. A method for fabricating an electrical-test prober space transformer, the method comprising:
receiving a substrate including a plurality of conductive traces and an array of conductive pins, each of the pins extending outwardly from a first pin end anchored to the substrate and electrically coupled to at least one of the conductive traces;
receiving a mold preform sheet comprising a polymer resin;
forming an array of perforations through the mold preform sheet; and
affixing the mold preform sheet to a surface of the substrate with the array of conductive pins passing through the array of perforations.

12. The method of claim 11, wherein forming the array of perforations further comprises selectively laser ablating the mold preform sheet.

13. The method of claim 12, wherein the laser ablating comprises forming a through hole having a minimum diameter less than 60 μm, and a sidewall angle no less than 70°.

14. The method of claim 12, wherein selectively laser ablating the mold preform sheet further comprises:
ablating a first thickness of the mold preform sheet by directing a laser light beam at a first angle of incidence along a first circular path defining the perforation perimeter; and
ablating a second thickness of the mold preform sheet by directing a laser light beam at a second angle of incidence along a second circular path intersecting a sidewall of the first thickness.

15. The method of claim 11, wherein the mold preform sheet comprises a resin composite material with a lateral coefficient of thermal expansion (CTE) of at least 9 ppm/° C. and a storage modulus of at least 15 GPa at 23° C.

16. The method of claim 15, wherein the resin composite has a glass transition temperature of at least 220° C.

17. The method of claim 16, wherein the resin composite comprises a polymeric matrix resin impregnated with filler.

18. The method of claim 11, wherein affixing the mold preform sheet to a surface of the substrate further comprises applying an adhesive to a surface of at least one of the mold preform sheet and substrate.

19. A method of testing a singulated unpackaged die, the method comprising:
aligning the die to an array of conductive pins disposed on a space transformer, the pins:
extending outwardly from first pin ends electrically coupled to conductive traces disposed on a space transformer substrate; and
passing through a perforated mold preform sheet affixed to a surface of the substrate by an adhesive, the mold preform sheet comprising a polymer resin;
contacting a top metallization level of the die with second pin ends of the conductive pin array; and
executing an electrical test algorithm on the die through the array of conductive pins.

20. The method of claim 19, wherein the mold preform sheet comprises a resin composite with a lateral coefficient of thermal expansion (CTE) of at least 9 ppm/° C. and a storage modulus of at least 15 GPa at 23° C., and has a glass transition temperature of at least 225° C.
